(19) United States
(12) Patent Application Publication
(10) Pub. No.: US 2014/0152905 A1
(43) Pub. Date: Jun. 5, 2014

(54) Display Device and Televison Set

(71) Applicant: Funai Electric Co., Ltd., Osaka (JP)

(72) Inventors: Akihiro FUJIKAWA, Daito-shi (JP); Akira YOKAWA, Daito-shi (JP); Yasuyuki FUKUMOTO, Daito-shi (JP)

(73) Assignee: Funai Electric Co., Ltd., Osaka (JP)

(21) Appl. No.: 14/090,239

(22) Filed: Nov. 26, 2013

(30) Foreign Application Priority Data
Nov. 30, 2012 (JP) 2012-261922

(51) Int. Cl. H05K 7/14; H04N 5/64

(52) U.S. Cl. CPC H05K 7/14; H04N 5/64
USPC 348/836; 361/679.01

(57) ABSTRACT

This display device includes a housing including an inner surface extending in an anteroposterior direction, a display portion arranged to be exposed from the front side of the housing, and a single board including a switch element arranged on a first surface and a remote control signal receiving element arranged on a second surface. The board is arranged to be opposed to the inner surface extending in the anteroposterior direction of the housing in substantially parallel to the inner surface.

### BACKGROUND OF THE INVENTION

1. Field of the Invention

The present invention relates to a display device and a television set, and more particularly, it relates to a display device and a television set each provided with a board.

2. Description of the Background Art

A display device provided with a board is known in general, as disclosed in Japanese Patent Laying-Open No. 2012-042580.

Japanese Patent Laying-Open No. 2012-042580 discloses a liquid crystal display device (display device) including a housing, a liquid crystal panel (display portion), a first X-PCB mounted with a switch (switch element) detecting a switching operation performed by a user's finger, and a second X-PCB mounted with a remote control receiving circuit (remote control signal receiving element) etc. provided separately from the first X-PCB, detecting an operation signal of a remote controller. The switch is mounted on a first surface of the first X-PCB. The remote control receiving circuit is mounted on a first surface of the second X-PCB.

The first X-PCB and the second X-PCB are opposed to each other while being parallel to a surface of the liquid crystal panel extending in an anteroposterior direction. Furthermore, the first X-PCB and the second X-PCB are conceivably opposed to each other while being parallel to the inner surface of the housing extending in the anteroposterior direction. In this liquid crystal display device, the first X-PCB and the second X-PCB are arranged parallel to the inner surface of the housing extending in the anteroposterior direction, whereby a space in a direction perpendicular to the anteroposterior direction for arranging the first X-PCB and the second X-PCB is reduced as compared with the case where the first X-PCB and the second X-PCB are arranged perpendicular to the anteroposterior direction. Thus, an increase in the width of a frame surrounding the liquid crystal panel is suppressed in this liquid crystal display device.

However, although the width of the frame is reduced by arranging the first X-PCB and the second X-PCB parallel to the inner surface of the housing extending in the anteroposterior direction in the display device according to Japanese Patent Laying-Open No. 2012-042580, the switch (switch element) detecting the switching operation performed by the user's finger and the remote control receiving circuit (remote control signal receiving element) detecting the operation signal of the remote controller are mounted on the first surfaces of the first X-PCB and the second X-PCB separated from each other, respectively, so that the structure of the liquid crystal display device (display device) is complicated. Thus, it is desirable to simplify the structure of the boards including the switch and the remote control receiving circuit of the display device.

### SUMMARY OF THE INVENTION

The present invention has been proposed in order to solve the aforementioned problem, and an object of the present invention is to provide a display device and a television set each capable of simplifying the structure of a board including a switch element and a remote control signal receiving element while a frame width is reduced.

A display device according to a first aspect of the present invention includes a housing including an inner surface extending in an anteroposterior direction, a display portion arranged to be exposed from the front side of the housing, and a single board including a switch element arranged on a first surface, detecting a switching operation and a remote control signal receiving element arranged on a second surface, detecting an input of an operation signal from a remote controller, while the board is arranged to be opposed to the inner surface extending in the anteroposterior direction of the housing in substantially parallel to the inner surface.

As hereinabove described, the display device according to the first aspect of the present invention is provided with the single board including the switch element detecting the switching operation and the remote control signal receiving element detecting the input of the operation signal from the remote controller, whereby the switch element and the remote control signal receiving element can be provided on the same board, and hence the structure of the board including the switch element and the remote control signal receiving element can be simplified, unlike the case where the switch element detecting a manual operation and the remote control signal receiving element detecting a remote control operation are provided on separate boards. Furthermore, the board is arranged to be opposed to the inner surface extending in the anteroposterior direction of the housing in substantially parallel to the inner surface, whereby a space in a direction perpendicular to the anteroposterior direction of the housing for arranging the board can be reduced as compared with the case where the board is arranged perpendicular to the anteroposterior direction of the housing, and hence an increase in the size of a frame of the display device can be suppressed. Consequently, the structure of the board including the switch element and the remote control signal receiving element can be simplified while the width of the display device is reduced. In addition, the switch element is arranged on the first surface of the single board, and the remote control signal receiving element is arranged on the second surface of the single board, whereby the switch element and the remote control signal receiving element can be mounted, using both surfaces of the board, and hence the switch element and the remote control signal receiving element can be efficiently mounted on the single board, unlike the case where both the switch element and the remote control signal receiving element are mounted only on one surface of the board. Consequently, the board can be easily downsized. Moreover, unlike the case where the remote control signal receiving element detecting the remote control operation is mounted on a different board from a board mounted with the switch element, the switch element and the remote control signal receiving element can be arranged on the front surface and the rear surface of the same board, so that a user can operate the remote controller directing the remote controller to a position where the switch element is arranged to allow the remote control signal receiving element to reliably receive the operation signal of the remote controller when the user previously knows the position of the switch element.

In the aforementioned display device according to the first aspect, the switch element is preferably arranged on a surface of the board opposed to the inner surface of a side surface extending in the anteroposterior direction orthogonal to the front surface of the housing, and the remote control signal receiving element is preferably arranged on a surface of the board opposite to a side opposed to the inner surface of the housing. According to this structure, operating force can be applied in the direction perpendicular to the anteroposterior direction when the user operates the switch element, and hence swinging of the display device (display portion) in the anteroposterior direction can be suppressed, unlike the case where the operating force is applied in the anteroposterior direction.

In this case, the switch element is preferably arranged on the surface of the board opposed to the inner surface of the side surface of a lower portion of the housing. According to this structure, the weight of the display device acts in a direction (vertical direction) opposite to a direction in which the operating force is applied when the user operates the switch element, and hence backlash of the display device in the vertical direction and displacement of the setting position of the display device can be easily suppressed.

In the aforementioned display device according to the first aspect, the board preferably has a substantially rectangular shape, and the board having the substantially rectangular shape is preferably arranged such that the short side thereof extends in the anteroposterior direction of the housing and the long side thereof extends in a direction orthogonal to the anteroposterior direction of the housing. According to this structure, the short side of the board having the substantially rectangular shape is arranged in the anteroposterior direction of the housing, and hence an increase in the size of the housing in the anteroposterior direction can be suppressed. Consequently, an increase in the size of the display device in the anteroposterior direction can be suppressed.

In this case, a plurality of switch elements are preferably provided and are preferably aligned in the direction orthogonal to the anteroposterior direction of the housing on the second surface of the board. According to this structure, the plurality of switch elements are aligned in the direction orthogonal to the anteroposterior direction of the housing, and hence the size of the board can be reduced in the anteroposterior direction. Consequently, the display device can be downsized in the anteroposterior direction.

In the aforementioned display device according to the first aspect, the housing preferably includes a through-hole provided on the front side, and the remote control signal receiving element arranged on the second surface of the board is preferably configured to be capable of detecting the operation signal of the remote controller input from the front side through the through-hole. According to this structure, the remote control signal receiving element can easily detect the operation signal of the remote controller input from the front side of the display portion.

In the aforementioned display device according to the first aspect, the board preferably includes an illuminance detecting element detecting the illuminance of the periphery of the housing and a light emitting device displaying the state of the display portion, each arranged on a surface of the board on which the remote control signal receiving element is arranged, in addition to the switch element and the remote control signal receiving element. According to this structure, the switch element, the remote control signal receiving element, the illuminance detecting element, and the light emitting device can be efficiently mounted on the single board, using both surfaces of the board.

In this case, the display device preferably further includes a single lens member arranged to cover the remote control signal receiving element, the illuminance detecting element, and the light emitting device, and the single lens member is preferably configured to reflect light as the operation signal of the remote controller to the board and allow the light to enter the remote control signal receiving element, reflect external light to the board and allow the external light to enter the illuminance detecting element, and reflect light indicating the state of the display portion, emitted from the light emitting device in a direction substantially parallel to the board and emit the light to the front side of the housing. According to this structure, the external signal and light can be reflected in a direction in which the remote control signal receiving element and the illuminance detecting element easily detect the signal and light by the single lens member, and hence the external signal and light can be reliably detected. Furthermore, light emitted in a direction perpendicular to the board from the light emitting device can be reflected to the front side of the display device by the single lens member, and hence the user can be reliably notified of the state of the display portion. In addition, the aforementioned plurality of reflection functions can be obtained by the single lens member, and hence an increase in the number of components can be suppressed without complicating the structure.

In the aforementioned structure including the lens member, the housing preferably includes a through-hole provided on the front side, the remote control signal receiving element arranged on the second surface of the board is preferably configured to be capable of detecting the operation signal of the remote controller input from the front side through the through-hole, and the through-hole is preferably provided at a position overlapping with the lens member as viewed in the anteroposterior direction of the housing on the front surface of the housing on the side of the second surface of the board on which the remote control signal receiving element is arranged. According to this structure, light incident through the through-hole can be incident on the remote control signal receiving element through the lens member provided at the position overlapping with the through-hole, and hence the board, the through-hole, and the lens member can be efficiently arranged.

In the aforementioned structure having the through-hole and the lens member overlapping with each other, the lens member preferably has a first inclination portion substantially orthogonally reflecting the external light to the board and a second inclination portion substantially orthogonally reflecting the light indicating the state of the display portion, emitted from the light emitting device to the front side of the housing. According to this structure, light can be substantially orthogonally reflected by the first inclination portion and the second inclination portion, and hence the board, the through-hole, and the lens member can be more efficiently arranged.

In the aforementioned structure including the lens member, the board preferably has a substantially rectangular shape, and a height from a surface of the board opposed to the inner surface extending in the anteroposterior direction of the housing to the tip of the lens member is preferably smaller than the length of the short side of the board along the anteroposterior direction of the housing. According to this structure, the space in the direction perpendicular to the anteroposterior direction of the housing for arranging the board can be reduced even when the lens member is provided on the board, as compared with the case where the board is arranged perpendicular to the anteroposterior direction of the housing.

In the aforementioned display device according to the first aspect, the housing is preferably made of resin and preferably includes a deflection-deformable button portion at a position corresponding to the switch element by forming a cut portion, and a ground pattern configured to discharge static electricity entering through the cut portion is preferably arranged in the vicinity of the switch element of the board to be exposed on a surface of the board. According to this structure, the static electricity entering the display device through the cut portion can be removed by the ground pattern when the button portion is pressed down, and hence malfunction of the switch element due to the static electricity entering when the button portion is pressed down can be suppressed.

In this case, the display device preferably further includes a bezel made of metal, provided inside the housing, and the ground pattern of the board is preferably electrically connected to the bezel. According to this structure, static electricity flowing to the ground pattern can be easily allowed to flow to the bezel to be discharged. In the aforementioned structure including the bezel, the ground pattern is preferably electrically connected to the bezel through a plate-like earth plate. According to this structure, the static electricity flowing to the ground pattern through the earth plate can be reliably and easily allowed to flow to the bezel to be discharged.

In the aforementioned display device according to the first aspect, the board preferably has a substantially rectangular shape and includes a first positioning portion formed on a long side and a second positioning portion formed on a first short side in a plan view, and the housing preferably includes a third positioning portion formed at a position corresponding to the first positioning portion, a fourth positioning portion formed at a position corresponding to the second positioning portion, and a fixing portion fixing the vicinity of a second short side of the board. According to this structure, the board can be fixed to the housing by the fixing portion in a state where positioning in a longitudinal direction with respect to the housing is performed on the board by the first positioning portion of the board and the third positioning portion of the housing and positioning in a short-side direction with respect to the housing is performed on the board by the second positioning portion of the board and the fourth positioning portion of the housing. Thus, the board can be easily and reliably fixed to a proper position in the housing.

A television set according to a second aspect of the present invention includes a housing including an inner surface extending in an anteroposterior direction, a display portion arranged to be exposed from the front side of the housing, a single board including a switch element arranged on a first surface, detecting a switching operation and a remote control signal receiving element arranged on a second surface, detecting an input of an operation signal from a remote controller, and a receiving portion capable of receiving a broadcast signal, while the board is arranged to be opposed to the inner surface extending in the anteroposterior direction of the housing in substantially parallel to the inner surface.

As hereinabove described, the television set according to the second aspect of the present invention is provided with the single board including the switch element detecting the switching operation and the remote control signal receiving element detecting the input of the operation signal from the remote controller, whereby the switch element and the remote control signal receiving element can be provided on the same board, and hence the structure of the board including the switch element and the remote control signal receiving element can be simplified, unlike the case where the switch element detecting a manual operation and the remote control signal receiving element detecting a remote control operation are provided on separate boards. Furthermore, the board is arranged to be opposed to the inner surface extending in the anteroposterior direction of the housing in substantially parallel to the inner surface, whereby a space in a direction perpendicular to the anteroposterior direction of the housing for arranging the board can be reduced as compared with the case where the board is arranged perpendicular to the anteroposterior direction of the housing, and hence an increase in the size of a frame of the television set can be suppressed. Consequently, the structure of the board including the switch element and the remote control signal receiving element can be simplified while the width of the television set is reduced. In addition, the switch element is arranged on the first surface of the single board, and the remote control signal receiving element is arranged on the second surface of the single board, whereby the switch element and the remote control signal receiving element can be mounted, using both surfaces of the board, and hence the switch element and the remote control signal receiving element can be efficiently mounted on the single board, unlike the case where both the switch element and the remote control signal receiving element are mounted only on one surface of the board. Consequently, the board can be easily downsized. Moreover, unlike the case where the remote control signal receiving element detecting the remote control operation is mounted on a different board from a board mounted with the switch element, the switch element and the remote control signal receiving element can be arranged on the front surface and the rear surface of the same board, so that a user can operate the remote controller directing the remote controller to a position where the switch element is arranged to allow the remote control signal receiving element to reliably receive the operation signal of the remote controller when the user previously knows the position of the switch element.

In the aforementioned television set according to the second aspect, the switch element is preferably arranged on a surface of the board opposed to the inner surface of a side surface extending in the anteroposterior direction orthogonal to the front surface of the housing, and the remote control signal receiving element is preferably arranged on a surface of the board opposite to a side opposed to the inner surface of the housing. According to this structure, operating force can be applied in the direction perpendicular to the anteroposterior direction when the user operates the switch element, and hence swinging of the television set (display portion) in the anteroposterior direction can be suppressed, unlike the case where the operating force is applied in the anteroposterior direction.

In this case, the switch element is preferably arranged on the surface of the board opposed to the inner surface of the side surface of a lower portion of the housing. According to this structure, the weight of the television set acts in a direction (vertical direction) opposite to a direction in which the operating force is applied when the user operates the switch element, and hence backlash of the television set (display portion) in the vertical direction and displacement of the setting position of the television set can be easily suppressed.

In the aforementioned television set according to the second aspect, the housing preferably includes a through-hole provided on the front side, and the remote control signal receiving element arranged on the second surface of the board is preferably configured to be capable of detecting the operation signal of the remote controller input from the front side through the through-hole. According to this structure, the remote control signal receiving element can easily detect the operation signal of the remote controller input from the front side of the display portion.

In the aforementioned television set according to the second aspect, the board preferably includes an illuminance detecting element detecting the illuminance of the periphery of the housing and a light emitting device displaying the state of the display portion, each arranged on a surface of the board on which the remote control signal receiving element is arranged, in addition to the switch element and the remote control signal receiving element. According to this structure, the switch element, the remote control signal receiving element, the illuminance detecting element, and the light emitting device can be efficiently mounted on the single board, using both surfaces of the board.

According to the present invention, as hereinabove described, the structure of the board including the switch element and the remote control signal receiving element can be simplified while the frame width is reduced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram showing the overall structure of a TV according to an embodiment of the present invention;

FIG. 2 is an exploded perspective view showing the overall structure of the TV according to the embodiment of the present invention;

FIG. 3 is a diagram showing an operation board mounted on a front cabinet of the TV according to the embodiment of the present invention;

FIG. 4 is an enlarged view showing the operation board mounted on the front cabinet of the TV according to the embodiment of the present invention;

FIG. 5 is a diagram showing the TV according to the embodiment of the present invention as viewed from the lower surface side;

FIG. 6 is a sectional view taken along the line 500-500 in FIG. 4;

FIG. 7 is a diagram showing the rear side of the front cabinet of the TV according to the embodiment of the present invention;

FIG. 8 is an enlarged view showing the rear side of the front cabinet of the TV according to the embodiment of the present invention;

FIG. 9 is a diagram showing the inner surface of the front cabinet of the TV according to the embodiment of the present invention as viewed from a Z1 side;

FIG. 10 is a diagram showing the front cabinet of the TV according to the embodiment of the present invention as viewed from the lower surface side;

FIG. 11 is a diagram showing a surface on the Z1 side of the operation board of the TV according to the embodiment of the present invention;

FIG. 12 is a diagram showing a surface on a Z2 side of the operation board of the TV according to the embodiment of the present invention;

FIG. 13 is a diagram showing an earth plate of the TV according to the embodiment of the present invention;

FIG. 14 is a diagram showing the front side of a lens member of the TV according to the embodiment of the present invention; and

FIG. 15 is a diagram showing the rear side of the lens member of the TV according to the embodiment of the present invention.

### DESCRIPTION OF THE PREFERRED EMBODIMENTS

An embodiment of the present invention is hereinafter described with reference to the drawings.

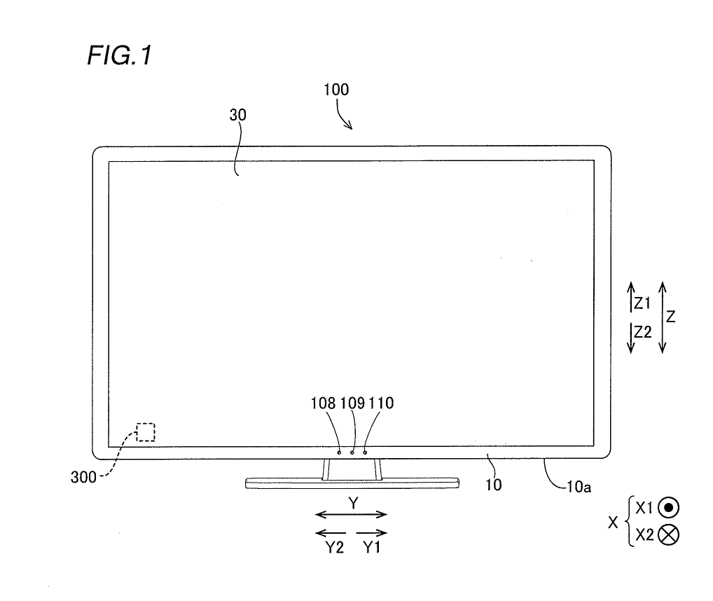

The structure of a TV (television set) 100 according to the embodiment of the present invention is now described with reference to FIGS. 1 to 15. The television set 100 is an example of the “display device” in the present invention.

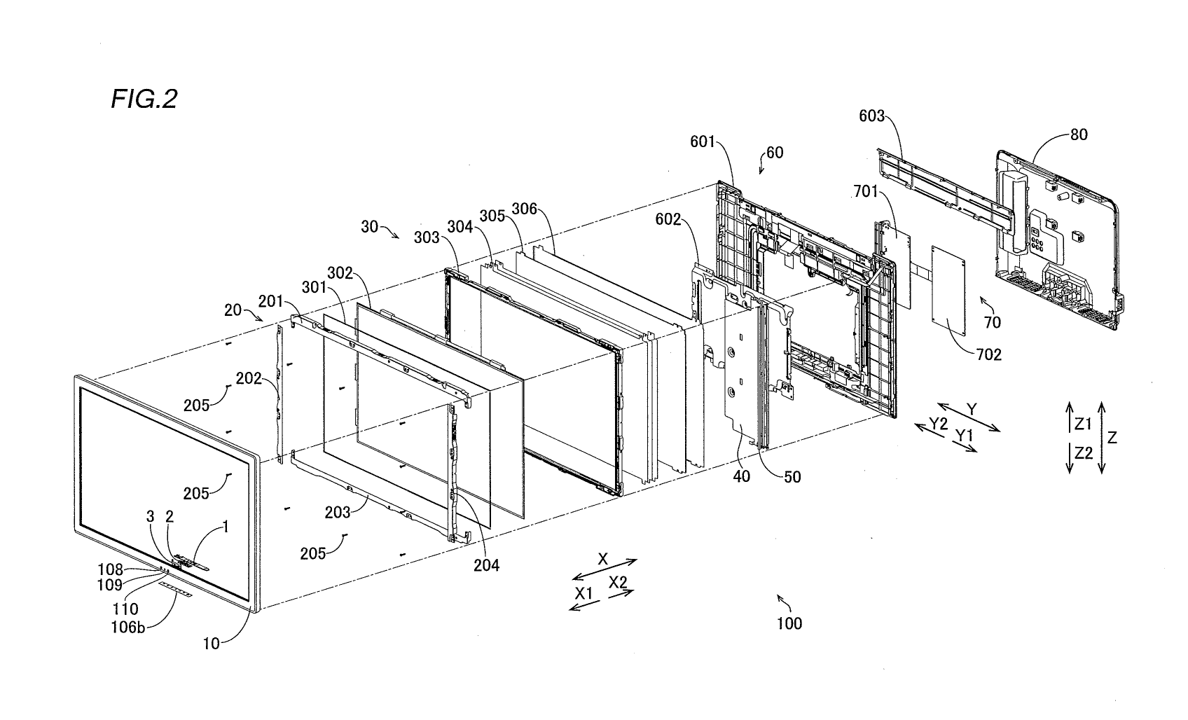

As shown in FIG. 1, the TV 100 according to the embodiment of the present invention includes a front cabinet 10 on the front side (X1 side) of the TV 100, as shown in FIG. 1. The TV 100 includes the front cabinet 10, a bezel 20, a liquid crystal module 30, a heat sink 40, an LED module 50, a rear cabinet 60, a main board 70, and a rear cover 80 in order from the front side, as shown in FIG. 2. The bezel 20, the liquid crystal module 30, the heat sink 40, and the LED module 50 are arranged between the front cabinet 10 and the rear cabinet 60. The front cabinet 10 is mounted with an operation board 1, a lens member 2, and an earth plate 3. The TV 100 is configured to be capable of receiving a broadcast signal by a tuner 300 (see FIG. 1). The front cabinet 10 is an example of the “housing” in the present invention. The operation board 1 is an example of the “board” in the present invention. The tuner 300 is an example of the “receiving portion” in the present invention.

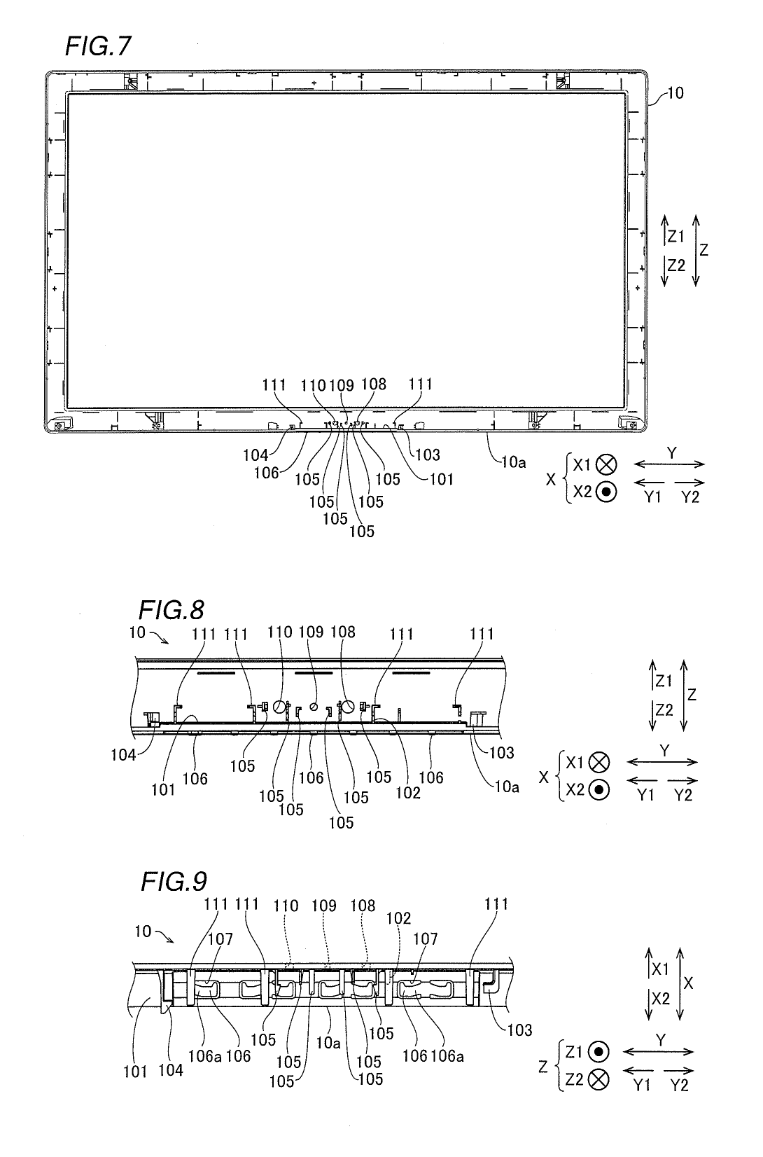

According to this embodiment, the front cabinet 10 is formed in a frame shape having a substantially rectangular shape in a plan view, as shown in FIGS. 1, 2, and 7. The front cabinet 10 is made of resin. The front cabinet 10 includes an inner surface 101 extending in an anteroposterior direction (direction X), as shown in FIGS. 7 and 8. The inner surface 101 is formed to be substantially parallel to the anteroposterior direction. As shown in FIGS. 4 and 6 to 9, a Y-direction positioning portion 102 (see FIG. 9), an X-direction positioning portion 103, and a fixing portion 104 are formed on the side of the inner surface 101 of the lower portion (Z2 side) of the front cabinet 10. The Y-direction positioning portion 102 and the X-direction positioning portion 103 each have a function of positioning the operation board 1 with respect to the front cabinet 10. The fixing portion 104 has a function of fixing the operation board 1 positioned with respect to the front cabinet 10 to the front cabinet 10. As shown in FIGS. 6 to 9, six lens fixing portions 105 configured to fix the lens member 2 to the front cabinet 10 are formed on the side of the inner surface 101 of the lower portion of the front cabinet 10. The operation board 1 has a thickness t, as shown in FIG. 4. The Y-direction positioning portion 102 is an example of the “third positioning portion” in the present invention. The X-direction positioning portion 103 is an example of the “fourth positioning portion” in the present invention.

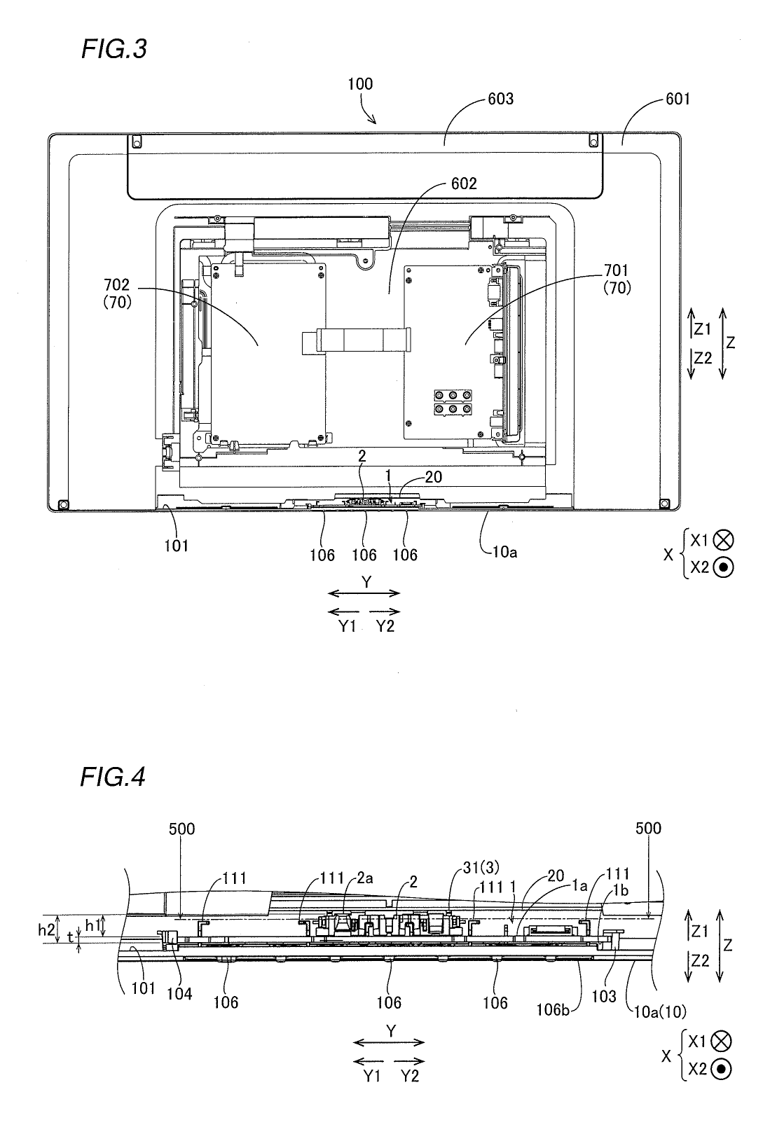

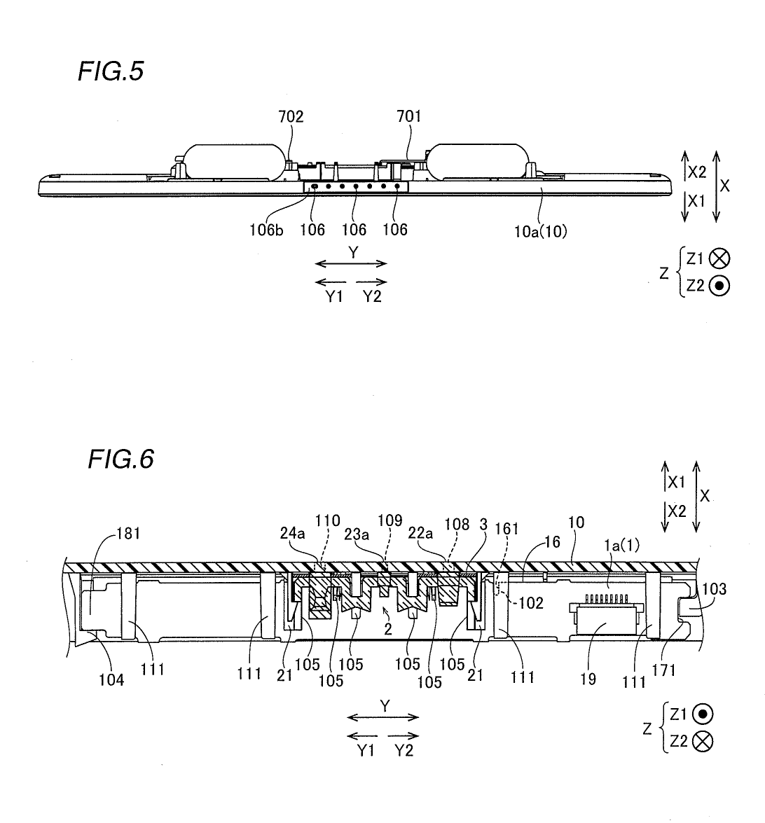

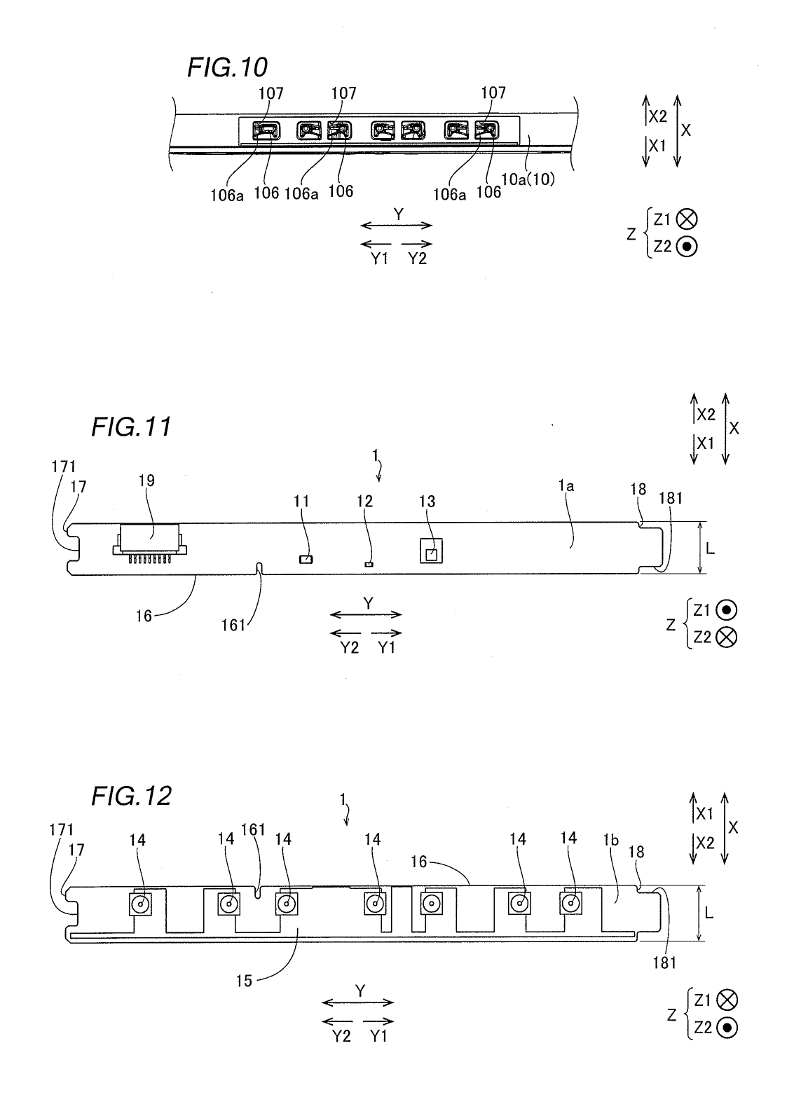

As shown in FIGS. 3 to 5 and 7 to 10, seven button portions 106 are formed on the lower edge 10a of the front cabinet 10 (see FIG. 1). Specifically, the front cabinet 10 includes the deflection-deformable button portions 106 at positions corresponding to tact switches 14 described later by forming cut portions 107, as shown in FIGS. 9 and 10. The button portions 106 are formed to be deflection-deformable, using connection portions 106a as fulcrums. As shown in FIG. 5, a seal member 106b formed to cover the periphery of the seven button portions 106 is attached to the front surface side (Z2 side) of the button portions 106. As shown in FIGS. 7 to 9, the Y-direction positioning portion 102, the X-direction positioning portion 103, the fixing portion 104, and the lens fixing portions 105, and the button portions 106 are integrally formed on the front cabinet 10. As shown in FIGS. 1 and 6 to 9, through-holes 108 to 110 configured to expose the lens member 2 are formed on the front side (X1 side) of the lower portion (Z2 side) of the front cabinet 10.

According to this embodiment, the operation board 1 is arranged to be opposed to the inner surface 101 extending in the anteroposterior direction (direction X) of the front cabinet 10 in substantially parallel to the inner surface 101, as shown in FIGS. 3 and 4. Specifically, the operation board 1 is arranged to be opposed to the inner surface 101 in a state where surfaces 1a and 1b of the operation board 1 are substantially parallel to the inner surface 101, as shown in FIG. 4. The operation board 1 is formed in a horizontally long shape (substantially rectangular shape) extending in a direction Y, as shown in FIGS. 11 and 12. The operation board 1 is arranged such that the short side thereof extends in the anteroposterior direction of the front cabinet 10 and the long side thereof extends in a direction orthogonal to the anteroposterior direction of the front cabinet 10, as shown in FIG. 2. The operation board 1 includes an illuminance sensor 11 detecting the illuminance of the periphery of the front cabinet 10, a remote control sensor 13 detecting an input of an operation signal from a remote controller, and an LED 12 displaying the state of a liquid crystal cell 302 on the surface 1a opposite (Z1 side) to a side opposed to the inner surface 101 of the front cabinet 10, as shown in FIG. 11. Specifically, the illuminance sensor 11 has a function of detecting the luminance of a setting place of the TV 100. The LED 12 is configured to emit light of a color (a red color in a standby state, for example) according to the power state of the TV 100. The remote control sensor 13 has a function of receiving an IR signal transmitted from the unshown remote controller. The illuminance sensor 11 is an example of the “illuminance detecting element” in the present invention. The LED 12 is an example of the “light emitting device” in the present invention. The remote control sensor 13 is an example of the “remote control signal receiving element” in the present invention. The surface 1a is an example of the “second surface” in the present invention. The surface 1b is an example of the “first surface” in the present invention.

The operation board 1 includes the seven tact switches 14 arranged on the surface 1b on a side (Z2 side) opposed to the inner surface 101 extending in the anteroposterior direction (direction X) of the front cabinet 10, detecting switching operations performed by a user's finger, as shown in FIG. 12. Specifically, the tact switches 14 are arranged on the surface 1b on the side (Z2 side) opposed to the inner surface 101 of a side surface extending in the anteroposterior direction (direction X) orthogonal to the front surface of the front cabinet 10. The tact switches 14 are arranged on the surface 1b of the operation board 1 on the side opposed to the inner surface 101 of the lower (Z2 side) side surface of the front cabinet 10. The seven tact switches 14 are configured to correspond to prescribed input operations (channel adjustment etc., for example). The seven tact switches 14 are aligned at prescribed intervals in the longitudinal direction (direction Y) of the operation board 1 orthogonal to the anteroposterior direction. The seven tact switches 14 are arranged at positions of the operation board 1 corresponding to the button portions 106 of the front cabinet 10. The button portions 106 are pressed down, whereby the tact switches 14 can switch between an on-state and an off-state. The illuminance sensor 11, the LED 12, the remote control sensor 13, and the tact switches 14 are mounted on the single operation board 1. The tact switches 14 are an example of the “switch element” in the present invention.

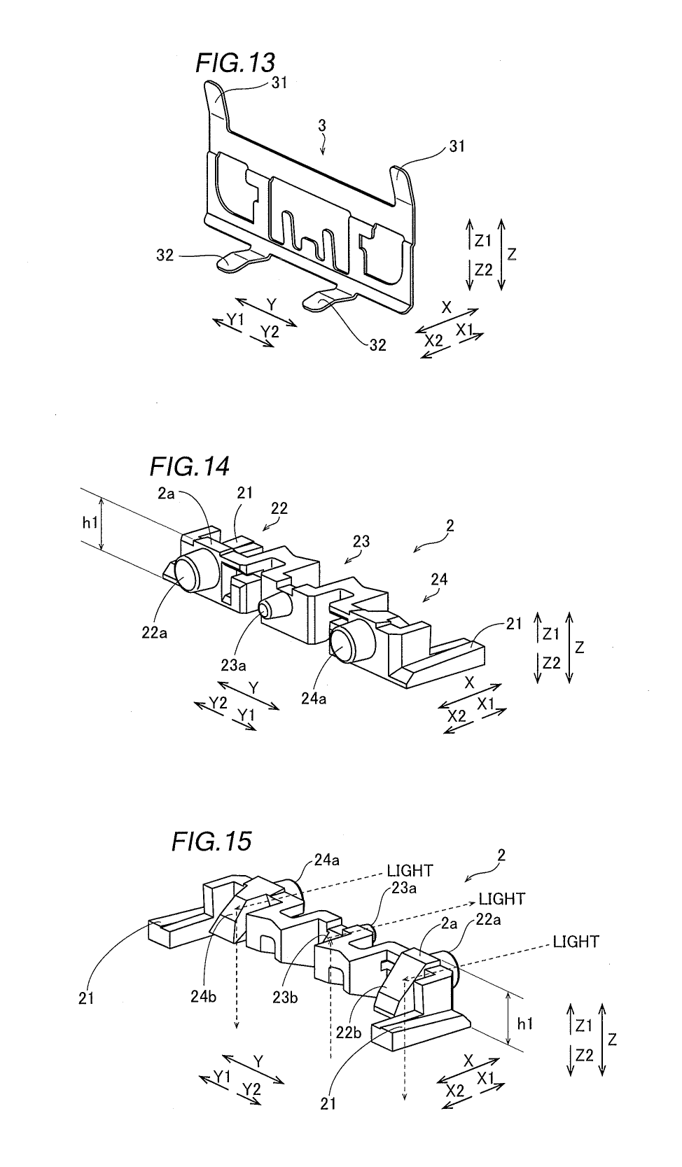

As shown in FIG. 12, in the vicinity of the tact switches 14, a ground pattern 15 for discharging static electricity entering through the cut portions 107 (see FIG. 10) when the user presses down the button portions 106 is arranged on the surface 1b of the operation board 1 to be exposed. Specifically, the ground pattern 15 is formed by providing no resist on the surface 1b of the operation board 1 on the Z2 side. The ground pattern 15 has a function of allowing static electricity entering the vicinity of the tact switches 14 to escape. The ground pattern 15 is electrically connected to the bezel 20 (see FIG. 2) through upper portions (see FIG. 13) of the earth plate 3 made of sheet metal, as shown in FIG. 4. The ground pattern 15 is configured to come into contact with lower portions 32 (see FIG. 13) of the earth plate 3.

As shown in FIGS. 11 and 12, the operation board 1 has a length L in a short-side direction (direction X). The operation board 1 includes a Y-direction positioning portion 161 formed on a long side 16 at a position corresponding to the Y-direction positioning portion 102 (see FIG. 8) of the front cabinet 10 in a plan view and an X-direction positioning portion 171 formed on a short side 17 at a position corresponding to the X-direction positioning portion 103 (see FIG. 8) of the front cabinet 10 in a plan view. The Y-direction positioning portion 161 has a function of positioning the operation board 1 with respect to the front cabinet 10 (see FIG. 1). The Y-direction positioning portion 161 has a notch shape. The Y-direction positioning portion 161 is configured to engage with the Y-direction positioning portion 102 of the front cabinet 10. The X-direction positioning portion 171 has a function of positioning the operation board 1 with respect to the front cabinet 10. The X-direction positioning portion 171 is formed by a recessed notch. The X-direction positioning portion 171 is configured to engage with the X-direction positioning portion 103 of the front cabinet 10, as shown in FIG. 6. The Y-direction positioning portion 161 is an example of the “first positioning portion” in the present invention. The X-direction positioning portion 171 is an example of the “second positioning portion” in the present invention.

As shown in FIGS. 11 and 12, a fixing portion 181 configured to fix the operation board 1 to the front cabinet 10 is formed on the short side 18 of the operation board 1 on a Y1 side. Specifically, the fixing portion 181 is formed in a convex shape to protrude toward the Y1 side. The fixing portion 181 is formed at a position corresponding to the fixing portion 104 (see FIG. 6) of the front cabinet 10. The fixing portion 181 engages with the fixing portion 104 of the front cabinet 10, whereby the operation board 1 is fixed to the front cabinet 10, as shown in FIG. 6. The operation board 1 fixed to the front cabinet 10 is suppressed from moving along arrow Z1 by uplift suppression portions 111 formed in the front cabinet 10.

According to this embodiment, the single lens member 2 (see FIG. 14) is arranged on the Z1 side of the operation board 1, as shown in FIGS. 3, 4, and 6. The lens member 2 is integrally formed of transparent or translucent resin (such as ABS (acrylonitrile butadiene styrene) resin) easily transmitting light. As shown in FIGS. 14 and 15, a pair of fixing portions 21 configured to fix the lens member 2 to the front cabinet 10 are formed on both ends of the lens member 2 in the direction Y. The fixing portions 21 engage with the lens fixing portions 105 (see FIG. 7) of the front cabinet 10. The lens member 2 has a height h1 in a direction Z. As shown in FIG. 4, a height h2 from the surface 1b of the operation board 1 on the side opposed to the inner surface 101 extending in the anteroposterior direction (direction X) of the front cabinet 10 to the tip 2a of the lens member 2 is smaller than the lengths L (see FIG. 11) of the short sides 17 and 18 of the operation board 1 along the anteroposterior direction of the front cabinet 10. In other words, a length (height h2) obtained by adding the thickness t of the operation board 1 and the height h1 of the lens member 2 is smaller than the lengths L of the short sides 17 and 18 of the operation board 1.

The lens member 2 includes an illuminance sensor lens 22, an LED lens 23, and a remote control sensor lens 24, as shown in FIGS. 14 and 15. The illuminance sensor lens 22, the LED lens 23, and the remote control sensor lens 24 are formed at positions corresponding to the illuminance sensor 11, the LED 12, and the remote control sensor 13 of the operation board 1 (see FIG. 11), respectively. The single lens member 2 is arranged to cover the illuminance sensor 11, the LED 12, and the remote control sensor 13 of the operation board 1. Specifically, the illuminance sensor lens 22, the LED lens 23, and the remote control sensor lens 24 of the lens member 2 are arranged to cover the illuminance sensor 11, the LED 12, and the remote control sensor 13 of the operation board 1, respectively.

The lens member 2 is configured to reflect light (infrared light) as a signal transmitted by the operation of the remote controller to the operation board 1 (see FIG. 1) and allow the light to enter the remote control sensor 13, reflect external light to the operation board 1 and allow the light to enter the illuminance sensor 11, and substantially orthogonally reflect light indicating the state of the liquid crystal cell 302, emitted from the LED 12 in a direction (direction X) substantially parallel to the operation board 1 and emit the light to the front side (X1 side) of the front cabinet 10, as shown in FIG. 15. The illuminance sensor lens 22 has an inclination portion 22b substantially orthogonally reflecting light of the setting position of the TV 100 entering through the through-hole 108 of the front cabinet 10 on the front side to the illuminance sensor 11. The LED lens 23 has an inclination portion 23b substantially orthogonally reflecting light emitted from the LED 12 and emitting the light to the front side (X1 side) of the TV 100 through the through-hole 109 on the front side. The remote control sensor lens 24 has an inclination portion 24b substantially orthogonally reflecting the IR signal (infrared light) entering from the unshown remote controller through the through-hole 110 of the front cabinet 10 on the front side. The remote control sensor 13 is configured to be capable of detecting a remote control operation signal input from the front side through the through-hole 110. As shown in FIG. 6, a protruding portion 22a of the illuminance sensor lens 22, a protruding portion 23a of the LED lens 23, and a protruding portion 24a of the remote control sensor lens 24 are configured to be exposed from the through-holes 108 to 110 of the front cabinet 10, respectively. In other words, the through-holes 108 to 110 are provided at a position overlapping with the lens member 2 as viewed in the anteroposterior direction of the front cabinet 10. The inclination portions 22b and 24b are examples of the “first inclination portion” in the present invention. The inclination portion 23b is an example of the “second inclination portion” in the present invention.

According to this embodiment, the bezel 20 is arranged on the front side (X1 side) of the liquid crystal module 30, as shown in FIGS. 2 and 4. The bezel 20 is provided inside the front cabinet 10. The bezel 20 is configured by fixing an upper portion 201, a right portion 202, a lower portion 203, and a left portion 204 to each other by screws 205, as shown in FIG. 2. The bezel 20 is formed in a frame shape as a whole. The bezel 20 is made of metal (sheet metal). The bezel 20 is grounded to be capable of discharging static electricity entering the TV 100.

The liquid crystal module 30 includes a diffusion sheet 301, the liquid crystal cell 302, a resin frame 303, an optical sheet 304, a light guide plate 305, and a reflective sheet 306, as shown in FIG. 2. The liquid crystal module 30 (liquid crystal cell 302) is arranged to be exposed from the front side (X1 side) of the front cabinet 10. The liquid crystal cell 302 is an example of the “display portion” in the present invention.

As shown in FIG. 2, the heat sink 40 is arranged on the rear side (X2 side) of the liquid crystal module 30. The heat sink 40 is arranged on the Y1 side as viewed from the front side (X1 side) of the TV 100. The LED module 50 allowing light to be incident on the light guide plate 305 is arranged on the heat sink 40. LEDs (semiconductor light emitting diodes) are arranged on the LED module 50 along a direction substantially parallel to a vertical direction (direction Z).

The rear frame 60 is arranged on the rear side (X2 side) of the heat sink 40, as shown in FIGS. 2 and 3. The rear frame 60 includes an outer frame portion 601 formed in a frame shape, a board mounting portion 602 arranged to be surrounded by the outer frame portion 601, and an upper frame portion 603 covering an upper portion (Z1 side) of the outer frame portion 601. The outer frame portion 601 and the upper frame portion 603 are made of resin. The outer frame portion 601 is formed substantially in a frame shape having a substantially rectangular shape. The board mounting portion 602 is made of sheet metal in a substantially rectangular shape.

The main board 70 is arranged on the rear side (X2 side) of the board mounting portion 602 of the rear frame 60, as shown in FIGS. 2 and 3. The main board 70 is constituted by a circuit board 701 for signal processing and a circuit board 702 for power supply generation. The rear cover 80 is arranged to cover the rear side (X2 side) of the main board 70 mounted on the rear frame 60 (board mounting portion 602). The circuit board 702 is connected to a connector 19 (FIG. 11) of the operation board 1 by an unshown wire.

A procedure for mounting the operation board 1 is now described with reference to FIGS. 4 and 6. First, the operation board 1 is arranged such that the surface 1b of the operation board 1 is opposed to the inner surface 101 of the front cabinet 10 mounted with the earth plate 3 (see FIG. 13), as shown in FIG. 4. At this time, the Y-direction positioning portion 161 of the operation board 1 engages with the Y-direction positioning portion 102 of the front cabinet 10, and positioning in the direction Y is performed on the operation board 1, as shown in FIG. 6. Furthermore, the X-direction positioning portion 171 of the operation board 1 engages with the X-direction positioning portion 103 of the front cabinet 10, and positioning in the direction X is performed on the operation board 1. In this state, the fixing portion 181 of the operation board 1 engages with the fixing portion 104 of the front cabinet 10, and the operation board 1 is fixed to the front cabinet 10. Then, the fixing portions 21 of the lens member 2 (see FIG. 15) engages with the lens fixing portions 105 of the operation board 1. At this time, the lens member 2 is mounted on the front cabinet 10 such that the protruding portions 22a, 23a, and 24a of the lens member 2 are exposed from the through-holes 108 to 110 of the front cabinet 10, respectively.

According to this embodiment, as hereinabove described, the tact switches 14 detecting the switching operations and the remote control sensor 13 detecting the input of the operation signal from the remote controller are mounted on the surfaces 1a and 1b of the single operation board 1, whereby the tact switches 14 and the remote control sensor 13 can be provided on the same operation board 1, and hence the structure of the operation board 1 including the tact switches 14 and the remote control sensor 13 can be simplified, unlike the case where the tact switches 14 and the remote control sensor 13 are provided on separate boards. Furthermore, the operation board 1 is arranged to be opposed to the inner surface 101 extending in the anteroposterior direction of the front cabinet 10 in substantially parallel to the inner surface 101, whereby a space in a direction perpendicular to the anteroposterior direction of the front cabinet 10 for arranging the operation board 1 can be reduced as compared with the case where the operation board 1 is arranged perpendicular to the anteroposterior direction of the front cabinet 10, and hence an increase in the size of a frame of the TV 100 can be suppressed. Consequently, the structure of the operation board 1 including the tact switches 14 and the remote control sensor 13 can be simplified while the width of the TV 100 is reduced. In addition, the tact switches 14 are arranged on the surface 1b of the single operation board 1, and the remote control sensor 13 is arranged on the surface 1a of the single operation board 1, whereby the tact switches 14 and the remote control sensor 13 can be mounted, using both surfaces of the operation board 1, and hence the tact switches 14 and the remote control sensor 13 can be efficiently mounted on the single operation board 1, unlike the case where both the tact switches 14 and the remote control sensor 13 are mounted only on one surface of the board. Consequently, the operation board 1 can be easily downsized. Moreover, unlike the case where the remote control sensor 13 detecting a remote control operation is mounted on a different board from a board mounted with the tact switches 14, the remote control sensor 13 and the tact switches 14 can be arranged on the surfaces 1a and 1b of the same operation board 1, so that the user can operate the remote controller directing the remote controller to positions where the tact switches 14 are arranged to allow the remote control sensor 13 to reliably receive the remote control operation signal when the user previously knows the positions of the tact switches 14.

According to this embodiment, the tact switches 14 are arranged on the surface 1b of the operation board 1 opposed to the inner surface 101 of the side surface extending in the anteroposterior direction orthogonal to the front surface of the front cabinet 10, and the remote control sensor 13 is arranged on the surface 1a of the operation board 1, whereby operating force can be applied in the direction perpendicular to the anteroposterior direction when the user operates the tact switches 14, and hence swinging of the TV 100 in the anteroposterior direction can be suppressed, unlike the case where the operating force is applied in the anteroposterior direction.

According to this embodiment, the tact switches 14 are arranged on the surface 1b of the operation board 1 opposed to the inner surface 101 of the lower side surface of the front cabinet 10, whereby the weight of the TV 100 acts in a direction (vertical direction) opposite to a direction in which the operating force is applied when the user operates the tact switches 14, and hence backlash of the TV 100 in the vertical direction and displacement of the setting position of the TV 100 can be easily suppressed.

According to this embodiment, the operation board 1 having the substantially rectangular shape is arranged such that the short side thereof extends in the anteroposterior direction of the front cabinet 10 and the long side thereof extends in the direction orthogonal to the anteroposterior direction of the front cabinet 10, whereby the short side of the operation board 1 having the substantially rectangular shape is arranged in the anteroposterior direction of the front cabinet 10, and hence an increase in the size of the front cabinet 10 in the anteroposterior direction can be suppressed. Consequently, an increase in the size of the TV 100 in the anteroposterior direction can be suppressed.

According to this embodiment, a plurality of tact switches 14 are provided and are aligned in the direction orthogonal to the anteroposterior direction of the front cabinet 10 on the surface 1a of the operation board 1, whereby the plurality of tact switches 14 are aligned in the direction orthogonal to the anteroposterior direction of the front cabinet 10, and hence the size of the operation board 1 can be reduced in the anteroposterior direction. Consequently, the TV 100 can be downsized in the anteroposterior direction.

According to this embodiment, the through-hole 110 is provided on the front side of the front cabinet 10, and the remote control sensor 13 is configured to be capable of detecting the remote control operation signal input from the front side through the through-hole 110, whereby the remote control sensor 13 can easily detect the remote control operation signal input from the front side.

According to this embodiment, the operation board 1 includes the illuminance sensor 11 and the LED 12 on the surface 1a on which the remote control sensor 13 is arranged in addition to the tact switches 14 and the remote control sensor 13, whereby the tact switches 14, the remote control sensor 13, the illuminance sensor 11, and the LED 12 can be efficiently mounted on the single operation board 1, using both surfaces of the operation board 1.

According to this embodiment, the single lens member 2 arranged to cover the remote control sensor 13, the illuminance sensor 11, and the LED 12 is provided, and the lens member 2 is configured to reflect the light as the operation signal of the remote controller to the operation board 1 and allow the light to enter the remote control sensor 13, reflect the external light to the operation board 1 and allow the light to enter the illuminance sensor 11, and reflect the light indicating the state of the liquid crystal cell 302, emitted from the LED 12 in the direction substantially parallel to the operation board 1 and emit the light to the front side of the front cabinet 10. Thus, the external signal and light can be reflected in a direction in which the remote control sensor 13 and the illuminance sensor 11 easily detect the signal and light by the single lens member 2, and hence the external signal and light can be reliably detected, and light emitted in a direction perpendicular to the operation board 1 from the LED 12 can be reflected to the front side of the TV 100. Thus, the user can be reliably notified of the state of the liquid crystal cell 302. Furthermore, the aforementioned plurality of reflection functions can be obtained by the single lens member 2, and hence an increase in the number of components can be suppressed without complicating the structure.

According to this embodiment, the through-hole 110 is provided at the position overlapping with the lens member 2 as viewed in the anteroposterior direction of the front cabinet 10 on the front surface of the front cabinet 10 on the side of the surface 1a of the operation board 1 on which the remote control sensor 13 is arranged. According to this structure, light incident through the through-hole 110 can be incident on the remote control sensor 13 through the lens member 2 provided at the position overlapping with the through-hole 110, and hence the operation board 1, the through-hole 110, and the lens member 2 can be efficiently arranged.

According to this embodiment, the lens member 2 is provided with the inclination portions 22b and 24b substantially orthogonally reflecting the external light to the operation board 1 and the inclination portion 23b substantially orthogonally reflecting the light indicating the state of the liquid crystal cell 302, emitted from the LED 12 to the front side of the front cabinet 10, whereby light can be substantially orthogonally reflected by the inclination portions 22b, 23b, and 24b, and hence the operation board 1, the through-hole 110, and the lens member 2 can be more efficiently arranged.

According to this embodiment, the operation board 1 is formed in the substantially rectangular shape, and the height h2 from the surface 1b of the operation board 1 on the side opposed to the inner surface 101 of the front cabinet 10 to the tip 2a of the lens member 2 is smaller than the lengths L of the short sides of the operation board 1 along the anteroposterior direction of the front cabinet 10, whereby the space in the direction perpendicular to the anteroposterior direction of the front cabinet 20 for arranging the operation board 1 can be reduced even when the lens member 2 is provided on the operation board 1, as compared with the case where the operation board 1 is arranged perpendicular to the anteroposterior direction of the front cabinet 10.

According to this embodiment, the button portions 106 are provided at the positions of the front cabinet 10 made of resin corresponding to the tact switches 14, and the ground pattern 15 is arranged in the vicinity of the tact switches 14 of the operation board 1 to be exposed, whereby static electricity entering the TV 100 through the cut portions 107 can be removed by the ground pattern 15, and hence malfunction of the tact switches 14 due to the static electricity can be suppressed.

According to this embodiment, the ground pattern 15 of the operation board 1 is electrically connected to the bezel 20 made of metal, whereby static electricity flowing to the ground pattern 15 can be easily allowed to flow to the bezel 20 to be discharged.

According to this embodiment, the ground pattern 15 is electrically connected to the bezel 20 through the plate-like earth plate 3, whereby the static electricity flowing to the ground pattern 15 through the earth plate 3 can be reliably and easily allowed to flow to the bezel 20 to be discharged.

According to this embodiment, the Y-direction positioning portion 161 and the X-direction positioning portion 171 are provided in the operation board 1, and the Y-direction positioning portion 102 formed at a position corresponding to the Y-direction positioning portion 161, the X-direction positioning portion 103 formed at a position corresponding to the X-direction positioning portion 171, and the fixing portion 104 fixing the operation board 1 are provided in the front cabinet 10, whereby the operation board 1 can be fixed to the front cabinet 10 in a state where the operation board 1 is positioned with respect to the front cabinet 10 by the Y-direction positioning portion 161, the Y-direction positioning portion 102, the X-direction positioning portion 171, and the X-direction positioning portion 103. Thus, the operation board 1 can be easily and reliably fixed to a proper position in the front cabinet 10.

The embodiment disclosed this time must be considered as illustrative in all points and not restrictive. The range of the present invention is shown not by the above description of the embodiment but by the scope of claims for patent, and all modifications within the meaning and range equivalent to the scope of claims for patent are further included.

For example, while the present invention is applied to the television set in the aforementioned embodiment, the present invention is not restricted to this. The present invention may alternatively be applied to a display device other than the television set. For example, the present invention may be applied to a display of a PC (personal computer) or the like.

While the operation board 1 is arranged in the front cabinet 10 in the aforementioned embodiment, the present invention is not restricted to this. According to the present invention, the board may alternatively be arranged in the rear cabinet as the housing.

While the switch element is the tact switches 14 in the aforementioned embodiment, the present invention is not restricted to this. According to the present invention, the switch element other than the tact switches 14, such as toggle switches may alternatively be employed.

While the light emitting device is the LED 12 in the aforementioned embodiment, the present invention is not restricted to this. According to the present invention, the light emitting device other than the LED 12 may alternatively be employed so far as the same can display the state of the display portion of the display device.

While the ground pattern 15 is integrally provided on the operation board 1 in the aforementioned embodiment, the present invention is not restricted to this. According to the present invention, a dedicated earth plate for countermeasure against static electricity may alternatively be provided separately from the board having the ground pattern 15.

While the operation board 1 is fixed to the front cabinet 10 by the fixing portion 104 of the front cabinet 10 in the aforementioned embodiment, the present invention is not restricted to this. According to the present invention, the board may alternatively be fixed to the housing by a double-faced adhesive tape or the like other than the fixing portion 104 of the housing, for example.

While the tact switches 14 are arranged on the surface 1b of the operation board 1 on the side opposed to the inner surface 101 of the lower side surface of the front cabinet 10 in the aforementioned embodiment, the present invention is not restricted to this. According to the present invention, the switch element may alternatively be arranged on a surface of the board on a side opposed to the inner surface of the upper, left, or right side surface of the housing.

What is claimed is:

1. A display device comprising:
a housing including an inner surface extending in an anteroposterior direction;
a display portion arranged to be exposed from a front side of the housing; and
a single board including a switch element arranged on a first surface, detecting a switching operation and a remote control signal receiving element arranged on a second surface, detecting an input of an operation signal from a remote controller, wherein
the board is arranged to be opposed to the inner surface extending in the anteroposterior direction of the housing in substantially parallel to the inner surface.

2. The display device according to claim 1, wherein
the switch element is arranged on a surface of the board opposed to the inner surface of a side surface extending in the anteroposterior direction orthogonal to a front surface of the housing, and
the remote control signal receiving element is arranged on a surface of the board opposite to a side opposed to the inner surface of the housing.

3. The display device according to claim 2, wherein
the switch element is arranged on the surface of the board opposed to the inner surface of the side surface of a lower portion of the housing.

4. The display device according to claim 1, wherein
the board has a substantially rectangular shape, and
the board having the substantially rectangular shape is arranged such that a short side thereof extends in the anteroposterior direction of the housing and a long side thereof extends in a direction orthogonal to the anteroposterior direction of the housing.

5. The display device according to claim 4, wherein
a plurality of switch elements are provided and are aligned in the direction orthogonal to the anteroposterior direction of the housing on the second surface of the board.

6. The display device according to claim 1, wherein
the housing includes a through-hole provided on the front side, and
the remote control signal receiving element arranged on the second surface of the board is configured to be capable of detecting the operation signal of the remote controller input from the front side through the through-hole.

7. The display device according to claim 1, wherein
the board includes an illuminance detecting element detecting an illuminance of a periphery of the housing and a light emitting device displaying a state of the display portion, each arranged on a surface of the board on which the remote control signal receiving element is arranged, in addition to the switch element and the remote control signal receiving element.

8. The display device according to claim 7, further comprising a single lens member arranged to cover the remote control signal receiving element, the illuminance detecting element, and the light emitting device, wherein
the single lens member is configured to reflect light as the operation signal of the remote controller to the board and allow the light to enter the remote control signal receiving element, reflect external light to the board and allow the external light to enter the illuminance detecting element, and reflect light indicating the state of the display portion, emitted from the light emitting device in a direction substantially parallel to the board and emit the light to the front side of the housing.

9. The display device according to claim 8, wherein
the housing includes a through-hole provided on the front side,
the remote control signal receiving element arranged on the second surface of the board is configured to be capable of detecting the operation signal of the remote controller input from the front side through the through-hole, and
the through-hole is provided at a position overlapping with the lens member as viewed in the anteroposterior direction of the housing on a front surface of the housing on a side of the second surface of the board on which the remote control signal receiving element is arranged.

10. The display device according to claim 9, wherein
the lens member has a first inclination portion substantially orthogonally reflecting the external light to the board and a second inclination portion substantially orthogonally reflecting the light indicating the state of the display portion, emitted from the light emitting device to the front side of the housing.

11. The display device according to claim 8, wherein
the board has a substantially rectangular shape, and
a height from a surface of the board opposed to the inner surface extending in the anteroposterior direction of the housing to a tip of the lens member is smaller than a length of a short side of the board along the anteroposterior direction of the housing.

12. The display device according to claim 1, wherein
the housing is made of resin and includes a deflection-deformable button portion at a position corresponding to the switch element by forming a cut portion, and
a ground pattern configured to discharge static electricity entering through the cut portion is arranged in a vicinity of the switch element of the board to be exposed on a surface of the board.

13. The display device according to claim 12, further comprising a bezel made of metal, provided inside the housing, wherein
the ground pattern of the board is electrically connected to the bezel.

14. The display device according to claim 13, wherein
the ground pattern is electrically connected to the bezel through a plate-like earth plate.

15. The display device according to claim 1, wherein
the board has a substantially rectangular shape and includes a first positioning portion formed on a long side and a second positioning portion formed on a first short side in a plan view, and
the housing includes a third positioning portion formed at a position corresponding to the first positioning portion, a fourth positioning portion formed at a position corresponding to the second positioning portion, and a fixing portion fixing a vicinity of a second short side of the board.

16. A television set comprising:
a housing including an inner surface extending in an anteroposterior direction;
a display portion arranged to be exposed from a front side of the housing;
a single board including a switch element arranged on a first surface, detecting a switching operation and a remote control signal receiving element arranged on a second surface, detecting an input of an operation signal from a remote controller; and
a receiving portion capable of receiving a broadcast signal, wherein
the board is arranged to be opposed to the inner surface extending in the anteroposterior direction of the housing in substantially parallel to the inner surface.

17. The television set according to claim 16, wherein
the switch element is arranged on a surface of the board opposed to the inner surface of a side surface extending in the anteroposterior direction orthogonal to a front surface of the housing, and
the remote control signal receiving element is arranged on a surface of the board opposite to a side opposed to the inner surface of the housing.

18. The television set according to claim 17, wherein
the switch element is arranged on the surface of the board opposed to the inner surface of the side surface of a lower portion of the housing.

19. The television set according to claim 16, wherein
the housing includes a through-hole provided on the front side, and
the remote control signal receiving element arranged on the second surface of the board is configured to be capable of detecting the operation signal of the remote controller input from the front side through the through-hole.

20. The television set according to claim 16, wherein
the board includes an illuminance detecting element detecting an illuminance of a periphery of the housing and a light emitting device displaying a state of the display portion, each arranged on a surface of the board on which the remote control signal receiving element is arranged, in addition to the switch element and the remote control signal receiving element.
